(19) United States
(12) Patent Application Publication
(10) Pub. No.: US 2025/0025908 A1
(43) Pub. Date: Jan. 23, 2025

(54) FLOW RATE ADJUSTMENT METHOD IN SUBSTRATE PROCESSING APPARATUS AND SUBSTRATE PROCESSING APPARATUS

(71) Applicant: TOKYO ELECTRON LIMITED, Tokyo (JP)

(72) Inventor: Hiroshi MARUMOTO, Kumamoto (JP)

(21) Appl. No.: 18/767,772

(22) Filed: Jul. 9, 2024

(30) Foreign Application Priority Data
Jul. 19, 2023 (JP) 2023-117599

(51) Int. Cl. B05C 11/10; B05C 5/02; B05C 11/08; B05C 13/02; H01L 21/67

(52) U.S. Cl. CPC B05C 11/1015; B05C 5/0225; B05C 11/08; B05C 13/02; H01L 21/6715; H01L 21/67207

(57) ABSTRACT

A flow rate adjustment method in a substrate processing apparatus including liquid processors performing liquid processing by supplying a mixed liquid of sulfuric acid and hydrogen peroxide to a substrate includes: discharging the mixed liquid under each discharge condition from first and second liquid processors; measuring a temperature of the mixed liquid for each discharge condition in the first and second liquid processors respectively; obtaining a correlation function between the temperature of the mixed liquid and a flow rate of sulfuric acid included in each discharge condition for the first and second liquid processors and thus generating a relational expression illustrating a sulfuric acid flow rate relationship when the temperature of the mixed liquid is identical between the first and second liquid processors; and adjusting the flow rate of sulfuric acid before being mixed into the mixed liquid in the second liquid processor by using the relational expression.

### CROSS-REFERENCE TO RELATED APPLICATION

This application is based upon and claims the benefit of priority from Japanese Patent Application No. 2023-117599, filed on Jul. 19, 2023 the entire contents of which are incorporated herein by reference.

### TECHNICAL FIELD

The present disclosure relates to a flow rate adjustment method in a substrate processing apparatus and the substrate processing apparatus.

### BACKGROUND

In a related art, a substrate processing apparatus that performs liquid processing by supplying a Sulfuric acid hydrogen Peroxide Mixture (SPM) liquid, which is a mixed liquid of sulfuric acid and hydrogen peroxide, to a substrate such as a semiconductor wafer is known.

### PRIOR ART DOCUMENT

### Patent Document

### Patent Document 1: Japanese laid-open publication No. 2009-16497

### SUMMARY

According to one embodiment of the present disclosure, there is provided a flow rate adjustment method in a substrate processing apparatus including a plurality of liquid processors configured to perform liquid processing by supplying a mixed liquid of sulfuric acid and hydrogen peroxide to a substrate, the flow rate adjustment method including: discharging the mixed liquid under a plurality of discharge conditions from a first liquid processor and a second liquid processor selected from among the plurality of liquid processors; measuring a temperature of the mixed liquid for each of the plurality of discharge conditions by using a temperature sensor provided in each of the first liquid processor and the second liquid processor; obtaining, based on the measured temperature of the mixed liquid, a correlation function between the temperature of the mixed liquid and a flow rate of sulfuric acid included in each of the plurality of discharge conditions for each of the first liquid processor and the second liquid processor, and generating, based on the correlation function, a relational expression illustrating a sulfuric acid flow rate relationship when the temperature of the mixed liquid is identical between the first liquid processor and the second liquid processor; and adjusting the flow rate of sulfuric acid before being mixed into the mixed liquid in the second liquid processor by using the relational expression.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a schematic configuration of a substrate processing system according to an embodiment.

FIG. 2 is a diagram illustrating a configuration of a processing unit according to the embodiment.

FIG. 3 is a diagram illustrating a specific configuration example of a processing liquid supply system in the substrate processing system according to the embodiment.

FIG. 4 is a flowchart illustrating a sequence of flow rate adjustment processing according to the embodiment.

FIG. 5 is a diagram illustrating an example for deriving a correlation function.

FIG. 6 is a diagram illustrating an example for generating a relational expression.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, a mode (referred to as “embodiment” below) for implementing a flow rate adjustment method in a substrate processing apparatus and the substrate processing apparatus according to the present disclosure is described in detail with reference to the drawings. In addition, the present disclosure is not limited by this embodiment.

In a related art, a substrate processing apparatus that performs liquid processing by supplying an SPM liquid, which is a mixed liquid of sulfuric acid and hydrogen peroxide, to a substrate such as a semiconductor wafer is known. Further, the substrate processing apparatus may include a plurality of liquid processors that perform the liquid processing by supplying the SPM liquid to the substrate.

However, in the substrate processing apparatus including the plurality of liquid processors, variations in temperature of the SPM liquid discharged respectively from the plurality of liquid processors may lead to variations in processing results among the plurality of liquid processors. The temperature of the SPM liquid from the plurality of liquid processors depends on flow rates of sulfuric acid and hydrogen peroxide in the respective liquid processors before being mixed into the SPM liquid, particularly the flow rate of sulfuric acid before being mixed into the SPM liquid.

Therefore, there is an expectation for the provision of a technique to adjust the flow rate of sulfuric acid before being mixed into the SPM liquid, in order to prevent variations in the temperature of the SPM liquid among the plurality of liquid processors.

A substrate processing apparatus according to an embodiment discharges an SPM liquid under a plurality of discharge conditions from a first liquid processor and a second liquid processor selected from among a plurality of liquid processors. Further, the substrate processing apparatus according to the embodiment measures a temperature of the SPM liquid under each of the plurality of discharge conditions for the first liquid processor and the second liquid processor by using a temperature sensor provided in each of the first liquid processor and the second liquid processor.

Further, the substrate processing apparatus according to the embodiment obtains a correlation function between the temperature of the SPM liquid and a flow rate of sulfuric acid included in each of the plurality of discharge conditions for each of the first liquid processor and the second liquid processor based on the measured temperature of the SPM liquid. Further, the substrate processing apparatus according to the embodiment generates a relational expression illustrating a sulfuric acid flow rate relationship when the temperature of the SPM liquid is identical between the first liquid processor and the second liquid processor, based on the correlation function. Then, the substrate processing apparatus according to the embodiment adjusts the flow rate of sulfuric acid before being mixed into the SPM liquid in the second liquid processor by using the relational expression.

In this way, the substrate processing apparatus according to the embodiment obtains the correlation between the temperature of the SPM liquid and the flow rate of sulfuric acid for each liquid processor, and adjusts the flow rate of sulfuric acid before being mixed into the SPM liquid in each liquid processor by using the sulfuric acid flow rate relationship when the temperature of the SPM liquid is identical among the plurality of liquid processors. Therefore, the substrate processing apparatus according to the embodiment may prevent variations in the temperature of the SPM liquid among the plurality of liquid processors, and therefore, may prevent variations in processing results among the plurality of liquid processors.

### <Outline of Substrate Processing System>

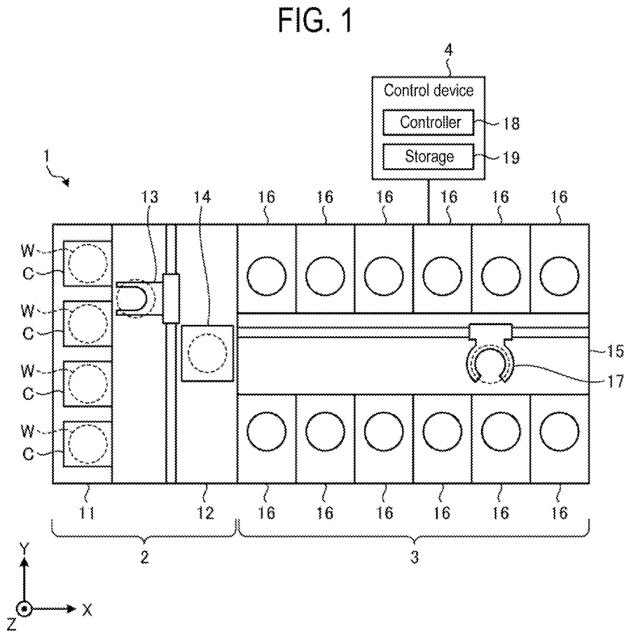

A schematic configuration of a substrate processing system 1 (an example of the substrate processing apparatus) according to the embodiment is described with reference to FIG. 1. FIG. 1 is a diagram illustrating the schematic configuration of the substrate processing system 1 according to the embodiment. In the following, the X-axis, Y-axis, and Z-axis, which are orthogonal to each other, are defined to clarify the positional relationships, with a positive direction of the Z-axis representing a vertical upward direction.

As illustrated in FIG. 1, the substrate processing system 1 includes a loading/unloading station 2 and a processing station 3. The loading/unloading station 2 and the processing station 3 are provided adjacent to each other.

The loading/unloading station 2 includes a carrier placement section 11 and a transfer section 12. In the carrier placement section 11, a plurality of carriers C, each accommodating a plurality of semiconductor wafers W (hereinafter referred to as wafers W (an example of substrates)) in a horizontal state, are placed.

The transfer section 12 is provided adjacent to the carrier placement section 11 and includes a substrate transfer device 13 and a deliverer 14 therein. The substrate transfer device 13 includes a substrate holder to hold the wafers W. Further, the substrate transfer device 13 is capable of moving in both horizontal and vertical directions as well as pivoting around a vertical axis. It transfers the wafers W between the carriers C and the deliverer 14 using the substrate holder.

The processing station 3 is provided adjacent to the transfer section 12. The processing station 3 includes a transfer section 15 and a plurality of processing units 16 (an example of the liquid processors). The plurality of processing units 16 are provided side by side on both sides of the transfer section 15.

The transfer section 15 includes a substrate transfer device 17 therein. The substrate transfer device 17 includes a substrate holder to hold the wafers W. Further, the substrate transfer device 17 is capable of moving in both the horizontal and vertical directions as well as pivoting around a vertical axis. It transfers the wafers W between the deliverer 14 and the processing units 16 using the substrate holder.

The processing units 16 perform predetermined substrate processings on the wafers W transferred by the substrate transfer device 17.

Further, the substrate processing system 1 includes a control device 4. The control device 4 is, for example, a computer and includes a controller 18 and a storage 19. The storage 19 stores programs that control various processes executed in the substrate processing system 1. The controller 18 controls an operation of the substrate processing system 1 by reading and executing the programs stored in the storage 19.

In addition, these programs may be recorded on a non-transient computer readable storage medium and may be installed from the storage medium into the storage 19 of the control device 4. Examples of the computer readable storage medium include a Hard Disk (HD), a Flexible Disk (FD), a Compact Disk (CD), a Magneto-Optical disk (MO), a memory card, etc.

In the substrate processing system 1 configured as described above, first, the substrate transfer device 13 of the loading/unloading station 2 retrieves the wafers W from the carriers C placed on the carrier placement section 11, and then places the retrieved wafers W onto the deliverer 14. The wafers W placed on the deliverer 14 are then retrieved from the deliverer 14 by the substrate transfer device 17 of the processing station 3 and are loaded into the processing units 16.

The wafers W loaded into the processing units 16 are processed by the processing units 16, and are then unloaded from the processing units 16 by the substrate transfer device 17 and are placed onto the deliverer 14. Then, the processed wafers W placed on the deliverer 14 are returned to the carriers C in the carrier placement section 11 by the substrate transfer device 13.

### <Outline of Processing Unit>

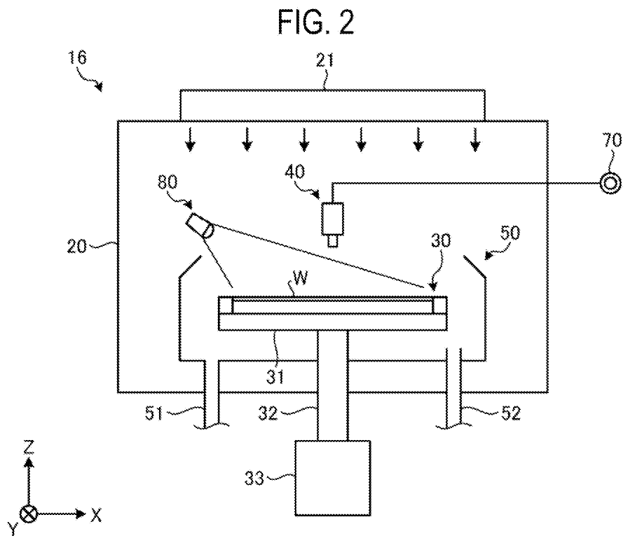

Next, a configuration of the processing unit 16 is described with reference to FIG. 2. FIG. 2 is a diagram illustrating the configuration of the processing unit 16 according to the embodiment. The processing unit 16 of the present embodiment supplies the SPM liquid, which is the mixed liquid of sulfuric acid and hydrogen peroxide, to the wafer W. As illustrated in FIG. 2, the processing unit 16 includes a chamber 20, a substrate holder 30, a nozzle 40 (an example of a discharger), a recovery cup 50, a temperature sensor 80, and an SPM supplier 70.

The chamber 20 accommodates the substrate holder 30, nozzle 40, recovery cup 50, and temperature sensor 80. A Fan Filter Unit (FFU) 21 is provided on a ceiling of the chamber 20. The FFU 21 forms a downflow within the chamber 20.

The substrate holder 30 includes a holder 31, a pillar 32, and a drive 33. The holder 31 holds the wafer W horizontally. The pillar 32 is a member extending in the vertical direction, with a base end rotatably supported by the drive 33 and a tip end horizontally supporting the holder 31. The drive 33 rotates the pillar 32 around a vertical axis. Such a substrate holder 30 rotates the holder 31 supported on the pillar 32 by rotating the pillar 32 using the drive 33, thereby rotating the wafer W held on the holder 31.

The nozzle 40 supplies the SPM liquid to the wafer W. The nozzle 40 is connected to the SPM supplier 70 to be described later, and discharges the SPM liquid supplied from the SPM supplier 70 to the wafer W.

The recovery cup 50 is disposed to surround the holder 31 and collects the SPM liquid scattered from the wafer W due to the rotation of the holder 31. A drain port 51 is formed at a bottom of the recovery cup 50, and the SPM liquid collected by the recovery cup 50 is discharged from the drain port 51 to an outside of the processing unit 16. Further, an exhaust port 52 is formed at the bottom of the recovery cup 50 to discharge a gas supplied from the FFU 21 to the outside of the processing unit 16.

The temperature sensor 80 is disposed adjacent to the nozzle 40 above the wafer W to measure the temperature of the SPM liquid on a surface of the wafer W. The temperature sensor 80 is provided in each of the plurality of processing units 16, so that the temperature of the SPM liquid on the surface of the wafer W may be measured for each of the plurality of processing units 16.

### <Configuration Example of Processing Liquid Supply System>

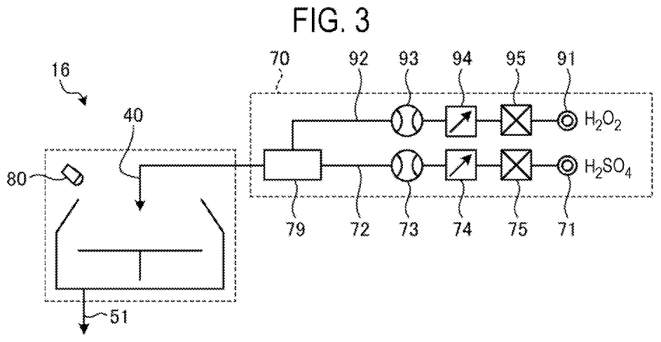

Next, a specific configuration example of a processing liquid supply system in the substrate processing system 1 according to the embodiment is described with reference to FIG. 3. FIG. 3 is a diagram illustrating the specific configuration example of the processing liquid supply system in the substrate processing system 1 according to the embodiment.

As illustrated in FIG. 3, the SPM supplier 70 serves as a sulfuric acid (H₂SO₄) supply system and includes a sulfuric acid source 71, a sulfuric acid supply path 72 (an example of a first path), a flow meter 73, a flow adjuster 74, and a valve 75. The sulfuric acid source 71 supplies sulfuric acid at a temperature set by the controller 18. The sulfuric acid supply path 72 connects the sulfuric acid source 71 to a mixer 79 to be described later, allowing the sulfuric acid supplied from the sulfuric acid source 71 to flow therethrough.

The flow meter 73 is provided in the sulfuric acid supply path 72 to measure a flow rate of sulfuric acid flowing through the sulfuric acid supply path 72. The flow adjuster 74 adjusts the flow rate of sulfuric acid flowing through the sulfuric acid supply path 72. Specifically, the flow adjuster 74 adjusts the flow rate of sulfuric acid flowing through the sulfuric acid supply path 72 based on a set flow rate set by the controller 18 such that a measured value by the flow meter 73 approaches the set flow rate. The valve 75 opens or closes the sulfuric acid supply path 72.

Further, the SPM supplier 70 serves as a hydrogen peroxide (H₂O₂) supply system, and includes a hydrogen peroxide source 91, a hydrogen peroxide supply path 92 (an example of a second path), a flow meter 93, a flow adjuster 94, and a valve 95. The hydrogen peroxide source 91 supplies hydrogen peroxide at ambient temperature (room temperature). The hydrogen peroxide supply path 92 connects the hydrogen peroxide source 91 to the mixer 79 to be described later, allowing the hydrogen peroxide supplied from the hydrogen peroxide source 91 to flow therethrough.

The flow meter 93 is provided in the hydrogen peroxide supply path 92 to measure a flow rate of hydrogen peroxide flowing through the hydrogen peroxide supply path 92. The flow adjuster 94 adjusts the flow rate of hydrogen peroxide flowing through the hydrogen peroxide supply path 92. Specifically, the flow adjuster 94 adjusts the flow rate of hydrogen peroxide flowing through the hydrogen peroxide supply path 92 based on a set flow rate set by the controller 18 such that a measured value by the flow meter 93 approaches the set flow rate. The valve 95 opens or closes the hydrogen peroxide supply path 92.

Further, the SPM supplier 70 includes the mixer 79. The mixer 79 mixes the sulfuric acid supplied from the sulfuric acid supply path 72 with the hydrogen peroxide supplied from the hydrogen peroxide supply path 92 at a preset mixing ratio to generate a mixed liquid, i.e. the SPM liquid. The generated SPM liquid is supplied to the nozzle 40 and is discharged from the nozzle 40.

### <Flow Rate Adjustment Processing>

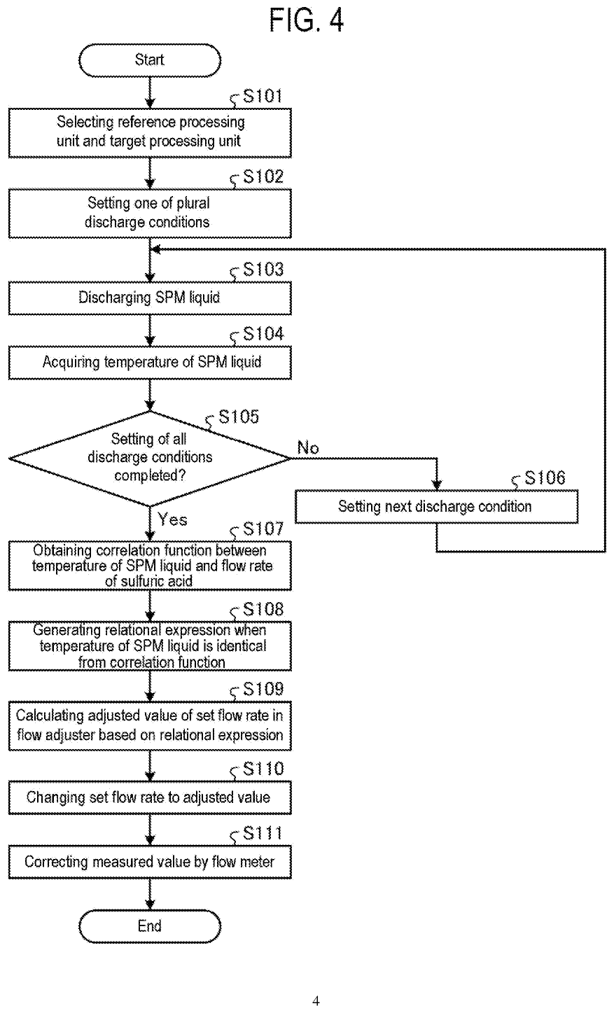

Next, the contents of flow rate adjustment processing for sulfuric acid before being mixed into the SPM liquid, which is executed by the controller 18 according to the embodiment, is described with reference to FIG. 4. FIG. 4 is a flowchart illustrating a sequence of flow rate adjustment processing according to the embodiment.

The flow rate adjustment processing illustrated in FIG. 4 is executed, for example, before performing substrate processing (liquid processing) on the wafer W using the processing unit 16. In addition, the flow rate adjustment processing illustrated in FIG. 4 may be executed at any timing, such as designated timing or periodic timing, separately from the timing before the substrate processing (liquid processing).

First, the controller 18 selects a reference processing unit (an example of the first liquid processor) and a target processing unit (an example of the second liquid processor) from the plurality of processing units 16 (step S101). The reference processing unit is the processing unit 16 used as a reference for an adjustment of the flow rate of sulfuric acid among the plurality of processing units 16. The target processing unit is the processing unit 16 used as a target for the adjustment of the flow rate of sulfuric acid among the plurality of processing units 16. In the following description, the reference processing unit is denoted as “processing unit 16R” and the target processing unit is denoted as “processing unit 16O.”

Next, the controller 18 sets one discharge condition from a plurality of discharge conditions, which are used when discharging the SPM liquid in the processing units 16R and 16O, in the processing units 16R and 16O (step S102). Each of the plurality of discharge conditions is composed of the temperature of sulfuric acid, the flow rate of sulfuric acid, and the flow rate of hydrogen peroxide. The plurality of discharge conditions differ from each other in at least one selected from the group of the temperature of sulfuric acid, the flow rate of sulfuric acid, and the flow rate of hydrogen peroxide. The controller 18 sets the temperature of sulfuric acid, the flow rate of sulfuric acid, and the flow rate of hydrogen peroxide, included in one of the plurality of discharge conditions, respectively to the sulfuric acid source 71, the flow adjuster 74, and the flow adjuster 94 in the processing units 16R and 16O.

The controller 18 loads the wafer W into both the chambers 20 of the processing units 16O and 16R by the substrate transfer device 17 (see FIG. 1), and controls the holder 31 of the substrate holder 30 to hold the wafer W. The wafer W may be a product wafer, or a dummy wafer for the flow rate adjustment. Thereafter, the controller 18 rotates the wafer W by rotating the holder 31 around the vertical axis using the drive 33 in the processing units 16O and 16R.

Next, with one of the plurality of processing conditions set in the processing units 16R and 16O, the controller 18 opens the valves 75 and 95 to discharge the SPM liquid to the wafer W from the nozzle 40 in the processing units 16R and 16O (step S103). When the SPM liquid begins to be discharged to the wafer W, the flow adjuster 74 of the processing units 16R and 16O adjusts the flow rate of sulfuric acid flowing through the sulfuric acid supply path 72 such that the measured value by the flow meter 73 approaches the set flow rate. Further, the flow adjuster 94 of the processing units 16R and 16O adjusts the flow rate of hydrogen peroxide flowing through the hydrogen peroxide supply path 92 such that the measured value by the flow meter 93 approaches the set flow rate.

Next, the controller 18 acquires the temperature of the SPM liquid in the processing unit 16R and the temperature of the SPM liquid in the processing unit 16O from the respective temperature sensors 80 of the processing units 16R and 16O (step S104). The controller 18 acquires the temperature of the SPM liquid in the processing unit 16R and the temperature of the SPM liquid in the processing unit 16O for each of the plurality of discharge conditions.

Next, the controller 18 determines whether or not all discharge conditions have been set completely in the processing units 16R and 16O (step S105). If they have not been set completely (step S105 “No”), the controller 18 sets the next discharge condition in the processing units 16R and 16O (step S106). Then, the processing returns to step S103.

On the other hand, if all discharge conditions have been set completely (step S105 “Yes”), the controller 18 obtains a correlation function between the temperature of the SPM liquid and the flow rate of sulfuric acid included in the discharge conditions for each of the processing units 16R and 16O, based on the temperature of the SPM liquid (step S107).

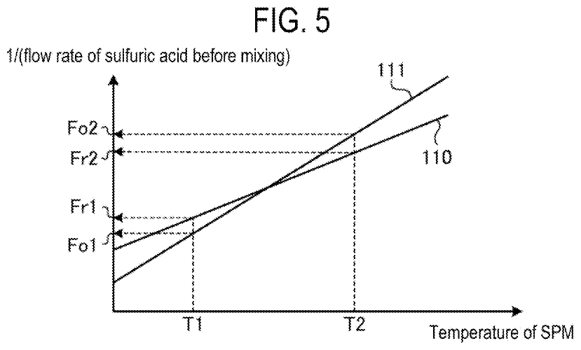

FIG. 5 is a diagram illustrating an example for deriving the correlation function. As a result of extensive research, the inventors of the present disclosure have found that a relationship among the temperature of the SPM liquid in each processing unit 16, the temperature of sulfuric acid before being mixed, and the flow rates of sulfuric acid and hydrogen peroxide before being mixed are represented by the following equation (1):
(Temperature of SPM liquid in each processing unit 16)=a+b·(Temperature of sulfuric acid before being mixed)+c·(Flow rate of hydrogen peroxide before being mixed)/{(Flow rate of sulfuric acid before being mixed)+(Flow rate of hydrogen peroxide before being mixed)}−(1)

Herein, a, b, and c are coefficients obtained through analysis, experimentation, etc.

From Equation (1), it may be understood that the temperature of the SPM liquid in each processing unit 16 is inversely correlated with the flow rate of sulfuric acid (sulfuric acid flowing through the sulfuric acid supply path 72) before being mixed into the SPM liquid.

Therefore, the controller 18 plots, for each of the processing units 16R and 16O, the temperature of the SPM liquid and the flow rate of sulfuric acid included in the corresponding discharge condition on a two-dimensional plane with the temperature of the SPM liquid in each processing unit 16 and the inverse of the flow rate of sulfuric acid before being mixed into the SPM liquid as respective dimensions thereof. Then, the controller 18 obtains, for each of the processing units 16R and 16O, an approximation line in plotting the temperature of the SPM liquid and the flow rate of sulfuric acid on the two-dimensional plane as a correlation function between the temperature of the SPM liquid in each processing unit 16 and the flow rate of sulfuric acid before being mixed into SPM liquid. Specifically, the controller 18 may obtain the correlation function between the temperature of the SPM liquid and the flow rate of sulfuric acid before being mixed into the SPM liquid for each of the processing units 16R and 16O using the approximation lines represented by the following equations (2) and (3):
(Temperature of SPM liquid in processing unit 16R)=α₀+α₁·1(Flow rate of sulfuric acid before being mixed)−(2)
(Temperature of SPM liquid in processing unit 16O)=α₂+α₃·1/(Flow rate of sulfuric acid before being mixed)−(3)

In FIG. 5, a correlation line 110 illustrates a correlation function (i.e., correlation function of Equation (2)) between the temperature of the SPM liquid in the processing unit 16R and the flow rate of sulfuric acid before being mixed into the SPM liquid. Further, in FIG. 5, a correlation line 111 illustrates a correlation function (i.e., correlation function of Equation (3)) between the temperature of the SPM liquid in the processing unit 16O and the flow rate of sulfuric acid before being mixed into the SPM liquid.

Returning to the description of FIG. 4, next, the controller 18 generates a relational expression illustrating a sulfuric acid flow rate relationship when the temperature of the SPM liquid is identical between the processing unit 16R and the processing unit 16O based on the obtained correlation function (correlation lines 110 and 111) (step S108).

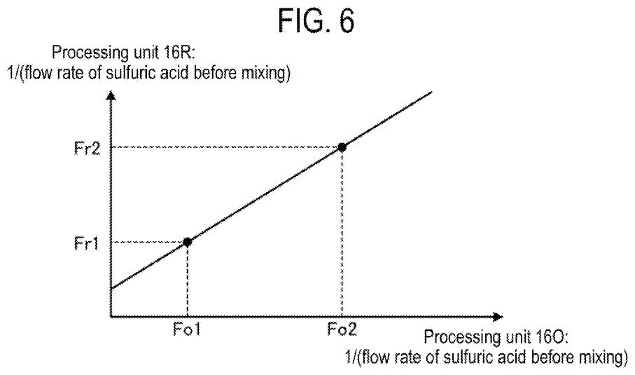

FIG. 6 is a diagram illustrating an example for generating the relational expression. The controller 18 acquires the flow rate of sulfuric acid when the temperature of the SPM liquid is identical between the processing unit 16R and the processing unit 16O from the correlation lines 110 and 111 (see FIG. 5). For example, the controller 18 acquires values Fr1 and Fo1 corresponding to a temperature T1 of the SPM liquid from the correlation lines 110 and 111 (see FIG. 5). Further, the controller 18 acquires values Fr2 and Fo2 corresponding to a temperature T2 of the SPM liquid from the correlation lines 110 and 111 (see FIG. 5).

Next, as illustrated in FIG. 6, the controller 18 plots the values Fr1, Fo1, Fr2 and Fo2 on a two-dimensional plane with an inverse of the flow rate of sulfuric acid before being mixed in the processing unit 16R and an inverse of the flow rate of sulfuric acid before being mixed in the processing unit 16O as respective dimensions thereof. Then, the controller 18 generates an equation illustrating an approximation line in plotting the values Fr1, Fo1, Fr2 and Fo2 on the two-dimensional plane as a relational expression. Specifically, the controller 18 may generate the relational expression illustrating a sulfuric acid flow rate relationship when the temperature of the SPM liquid is identical between the processing unit 16R and the processing unit 16O based on the approximation line represented by the following equation (4):
1/(Flow rate of sulfuric acid before being mixed in processing unit 16R)=β₀+β₁·1/(Flow rate of sulfuric acid before being mixed in processing unit 16O)−(4)

Returning to the description of FIG. 4, next, the controller 18 adjusts the flow rate of sulfuric acid before being mixed into the SPM liquid in the processing unit 16O using the relational expression. In other words, the controller 18 applies a “prescribed value,” which is set as the set flow rate in the flow adjuster 74 of the processing unit 16R, to the relational expression to calculate an adjusted value of the set flow rate in the flow adjuster 74 of the processing unit 16O (step S109). The “prescribed value” may be, for example, a value prescribed by a processing recipe for the substrate processing (liquid processing) on the wafer W. The prescribed value may also be a value commonly set to the set flow rates in the flow adjusters 74 of the processing units 16R and 16O.

Subsequently, the controller 18 changes the set flow rate in the flow adjuster 74 of the processing unit 16O from the “prescribed value” to the adjusted value calculated in step S109 (step S110). When the set flow rate is changed, the flow adjuster 74 of the processing unit 16O adjusts the flow rate of sulfuric acid flowing through the sulfuric acid supply path 72 such that a measured value by the flow meter 73 approaches the changed set flow rate (i.e., adjusted value). Herein, the adjusted value is calculated from the relational expression illustrating the sulfuric acid flow rate relationship when the temperature of the SPM liquid is identical between the processing unit 16R and the processing unit 16O. Therefore, the controller 18 may adjust the flow rate of sulfuric acid flowing through the sulfuric acid supply path 72 of the processing unit 16O (i.e., sulfuric acid before being mixed into the SPM liquid) to ensure that the temperature of the SPM liquid is identical between the processing unit 16R and the processing unit 16O.

In this way, the controller 18 determines the correlation between the temperature of the SPM liquid and the flow rate of sulfuric acid for each of the processing units 16R and 16O, and generates the relational expression for the flow rate of sulfuric acid when the temperature of the SPM liquid is identical between the processing units. Then, the controller 18 adjusts the flow rate of sulfuric acid before being mixed into the SPM liquid in the processing unit 16O by using the relational expression. Thus, variations in the temperature of the SPM liquid between the processing unit 16R and the processing unit 16O may be prevented, so that variations in processing results between the processing unit 16R and the processing unit 16O may be prevented.

After changing the set flow rate in the flow adjuster 74 of the processing unit 16O, the controller 18 corrects the measured value by the flow meter 73 of the processing unit 16O to the “prescribed value” (step S111). This may allow canceling errors in the measured value by the flow meter 73 resulted from individual differences of the flow meters 73 among the processing units 16, etc.

As described above, the flow rate adjustment method according to the embodiment is a flow rate adjustment method in a substrate processing apparatus (e.g., substrate processing system 1) including a plurality of liquid processors (e.g., processing units 16) that perform liquid processing by supplying a mixed liquid of sulfuric acid and hydrogen peroxide (e.g., SPM liquid) to a substrate (e.g., wafer W), and includes the steps of discharging, measuring, generating, and adjusting. The discharging step involves discharging the mixed liquid under a plurality of discharge conditions from a first liquid processor (e.g., processing unit 16R) and a second liquid processor (e.g., processing unit 16O) selected from among the plurality of liquid processors. The measuring step involves measuring a temperature of the mixed liquid for each of the plurality of discharge conditions by using a temperature sensor (e.g., temperature sensor 80) provided in each of the first liquid processor and the second liquid processor. The generating step involves obtaining, based on the measured temperature of the mixed liquid, a correlation function (e.g., Equations (2) and (3)) illustrating a correlation between the temperature of the mixed liquid and a flow rate of sulfuric acid included in each of the plurality of discharge conditions for each of the first liquid processor and the second liquid processor, and generating, based on the correlation function, a relational expression (e.g., Equation (4)) illustrating a sulfuric acid flow rate relationship when the temperature of the mixed liquid is identical between the first liquid processor and the second liquid processor. The adjusting step involves adjusting the flow rate of sulfuric acid before being mixed into the mixed liquid in the second liquid processor by using the relational expression. Thus, according to the flow rate adjustment method of the embodiment, it is possible to prevent variations in processing results among the plurality of liquid processors.

Further, each of the plurality of liquid processors may include a first path (e.g., sulfuric acid supply path 72), a second path (e.g., hydrogen peroxide supply path 92), a mixer (e.g., mixer 79), a discharger (e.g., nozzle 40), a flow meter (e.g., flow meter 73), and a flow adjuster (e.g., flow adjuster 74). The first path allows the flow of sulfuric acid. The second path allows the flow of hydrogen peroxide. The mixer generates the mixed liquid by mixing sulfuric acid from the first path and hydrogen peroxide from the second path. The discharger discharges the mixed liquid generated by the mixer to the substrate. The flow meter is provided in the first path to measure the flow rate of sulfuric acid flowing through the first path. The flow adjuster is provided in the first path and adjusts, based on a set flow rate, the flow rate of sulfuric acid flowing through the first path such that a measured value by the flow meter approaches the set flow rate. Further, the adjusting step may involve applying a prescribed value set as the set flow rate in the flow adjuster of the first liquid processor to the relational expression to calculate an adjusted value of the set flow rate in the flow adjuster of the second liquid processor. Then, the adjusting step may involve adjusting the flow rate of sulfuric acid flowing through the first path of the second liquid processor by changing the set flow rate in the flow adjuster of the second liquid processor from the prescribed value to the adjusted value. Thus, according to the flow rate adjustment method of the embodiment, it is possible to prevent variations in the processing results among the plurality of liquid processors.

Further, the measuring step may involve measuring the temperature of the mixed liquid on a surface of the substrate by using the temperature sensor disposed adjacent to the discharger. Thus, according to the flow rate adjustment method of the embodiment, it is possible to allow easy measurement of the temperature of the mixed liquid on the surface of the substrate.

### <Modifications>

In the above-described embodiment, the temperature sensor 80 has been described as disposed adjacent to the nozzle 40, but the disposition position of the temperature sensor 80 is not limited thereto. For example, the temperature sensor 80 may be disposed in a pipe interconnecting the mixer 79 and the nozzle 40, or in the nozzle 40. In this case, the measuring step may involve measuring the temperature of the SPM liquid before being discharged from the nozzle 40 by using the temperature sensor 80 disposed in the pipe interconnecting the mixer 79 and the nozzle 40, or in the nozzle 40. This enables the easy measurement of the temperature of the mixed liquid before being discharged.

According to the present disclosure, it is possible to prevent variations in processing results among a plurality of liquid processors.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A flow rate adjustment method in a substrate processing apparatus including a plurality of liquid processors configured to perform liquid processing by supplying a mixed liquid of sulfuric acid and hydrogen peroxide to a substrate, the flow rate adjustment method comprising:
discharging the mixed liquid under a plurality of discharge conditions from a first liquid processor and a second liquid processor selected from among the plurality of liquid processors;
measuring a temperature of the mixed liquid for each of the plurality of discharge conditions by using a temperature sensor provided in each of the first liquid processor and the second liquid processor;
obtaining, based on the measured temperature of the mixed liquid, a correlation function between the temperature of the mixed liquid and a flow rate of sulfuric acid included in each of the plurality of discharge conditions for each of the first liquid processor and the second liquid processor, and generating, based on the correlation function, a relational expression illustrating a sulfuric acid flow rate relationship when the temperature of the mixed liquid is identical between the first liquid processor and the second liquid processor; and
adjusting the flow rate of sulfuric acid before being mixed into the mixed liquid in the second liquid processor by using the relational expression.

2. The flow rate adjustment method of claim 1, wherein each of the plurality of liquid processors includes:
a first path through which sulfuric acid flows;
a second path through which hydrogen peroxide flows;
a mixer configured to generate the mixed liquid by mixing sulfuric acid from the first path and hydrogen peroxide from the second path;
a discharger configured to discharge the mixed liquid generated by the mixer to the substrate;
a flow meter provided in the first path and configured to measure the flow rate of sulfuric acid flowing through the first path; and
a flow adjuster provided in the first path and configured to adjust, based on a set flow rate, the flow rate of sulfuric acid flowing through the first path so that a measured value by the flow meter approaches the set flow rate, and
wherein the adjusting includes:
applying a prescribed value set on the set flow rate in the flow adjuster of the first liquid processor to the relational expression to calculate an adjusted value of the set flow rate in the flow adjuster of the second liquid processor; and
adjusting the flow rate of sulfuric acid flowing through the first path of the second liquid processor by changing the set flow rate in the flow adjuster of the second liquid processor from the prescribed value to the adjusted value.

3. The flow rate adjustment method of claim 2, wherein the adjusting includes correcting the measured value by the flow meter of the second liquid processor to the prescribed value after changing the set flow rate.

4. The flow rate adjustment method of claim 2, wherein the measuring includes measuring the temperature of the mixed liquid on a surface of the substrate by using the temperature sensor disposed adjacent to the discharger.

5. The flow rate adjustment method of claim 2, wherein the measuring includes measuring the temperature of the mixed liquid before being discharged from the discharger by using the temperature sensor disposed in a pipe interconnecting the mixer and the discharger, or in the discharger.

6. A substrate processing apparatus comprising:
a plurality of liquid processors configured to perform liquid processing by supplying a mixed liquid of sulfuric acid and hydrogen peroxide to a substrate;
a temperature sensor provided in each of the plurality of liquid processors and configured to measure a temperature of the mixed liquid; and
a controller,
wherein the controller is configured to cause each part to execute a flow rate adjustment method including:
discharging the mixed liquid under a plurality of discharge conditions from a first liquid processor and a second liquid processor selected from among the plurality of liquid processors;
measuring the temperature of the mixed liquid for each of the plurality of discharge conditions by using the temperature sensor provided in each of the first liquid processor and the second liquid processor;
obtaining, based on the measured temperature of the mixed liquid, a correlation function between the temperature of the mixed liquid and a flow rate of sulfuric acid included in each of the plurality of discharge conditions for each of the first liquid processor and the second liquid processor, and generating, based on the correlation function, a relational expression illustrating a sulfuric acid flow rate relationship when the temperature of the mixed liquid is identical between the first liquid processor and the second liquid processor; and
adjusting the flow rate of sulfuric acid before being mixed into the mixed liquid in the second liquid processor by using the relational expression.
